(19) United States
(12) Patent Application Publication
(10) Pub. No.: US 2006/0062914 A1
(43) Pub. Date: Mar. 23, 2006

(54) Apparatus and process for surface treatment of substrate using an activated reactive gas

(76) Inventors: Diwakar Garg, Emmaus, PA (US); Steven Arnold Krouse, Tamaqua, PA (US); Eric Anthony Robertson III, Easton, PA (US)

Correspondence Address: AIR PRODUCTS AND CHEMICALS, INC.;PATENT DEPARTMENT, 7201 HAMILTON BOULEVARD, ALLENTOWN, PA, 181951501, US

(21) Appl. No.: 11/080,330

(22) Filed: Mar. 15, 2005

Related U.S. Application Data
(60) Provisional application No. 60/612,060, filed on Sep. 21, 2004.

(51) Int. Cl. C23C 16/00

(52) U.S. Cl. 427/248.1; 118/723 R

(57) ABSTRACT

An apparatus and process for treating at least a portion of the surface of a substrate is described herein. In one aspect, the apparatus a processing chamber comprising an inner volume, the substrate, and an exhaust manifold; an activated reactive gas supply source wherein a process gas comprising one or more reactive gases and optionally an additive gas is activated by one or more energy sources to provide the activated reactive gas; and a distribution conduit, which is in fluid communication with the inner volume and the supply source, comprising: a plurality of openings that direct the activated reactive gas into the inner volume, wherein the activated reactive gas contacts the surface and provides a spent activated reactive gas and/or volatile products that are withdrawn from the inner volume through the exhaust manifold.

### CROSS-REFERENCE TO RELATED APPLICATIONS

This application claims the benefit of U.S. Provisional Application No. 60/612,060, filed 21 Sep. 2004.

### BACKGROUND OF THE INVENTION

Surface treatment of relatively wide and/or large areas (e.g., 4 feet wide or greater and/or 4 feet long or greater) of a variety of substrates including glass, metals, semi-metals, polymers, ceramics and plastics, as well as substrates such as glass, metals, semi-metals, polymers, ceramics and plastics and deposited with a wide variety of coatings, is becoming increasingly important to a variety of industries. In this connection, proposals have been made to treat surfaces of polymers, plastics and metals, semi-metals and ceramics to improve their adhesion and/or bonding to other materials; polymers and plastics to change their gas and liquid permeation properties; polymers, plastics, glass and ceramics to impart them hydrophilic or hydrophobic properties; coated and uncoated polymers, plastics, metals, semi-metals, ceramics and glass to remove undesirable surface contaminants such as moisture, oil, etc., and/or uncoated and coated polymers, plastics, glass and ceramics to change their optical characteristics such as light absorption, transmission, reflection and scattering. Many of these surface treatments of materials are conducted using reactive gases that are activated inside a processing chamber using plasma generated by a source such as ion beam, DC discharge, radio frequency (RF), medium to high frequency devices, and/or or microwave (MW).

A well known method for removing unwanted materials from a processing chamber, such as a chemical vapor deposition (CVD) reactor for semiconductor manufacturing, is to introduce an activated reactive gas containing active species (i.e., ions, free radicals, electrons, particles, etc.) into the chamber to etch away the unwanted deposits. For example, silicon oxide deposited on the walls of a plasma enhanced CVD (PECVD) reactor during its deposition on a semiconductor substrate is commonly removed by activating a mixture of reactive gases such as C₂F₆ and O₂ or NF₃ gas with plasma within the reactor in a method which is referred to herein as an “in situ plasma cleaning”. Alternatively, silicon oxide deposits may be removed by activating the reactive gas in a location outside of the reactor by plasma and introducing the activated species into the reactor in a method which is referred to herein as “remote plasma cleaning”.

The above techniques for removing unwanted deposits from the walls of a CVD reactor with plasma activated reactive gas—where the reactive gas is activated either with an in-situ plasma source or by using a remote plasma source—can also be used to treat surfaces of various substrates for the purposes described herein. For example, surfaces of these materials can be treated with appropriate activated reactive gas to roughen or smooth the uncoated or coated substrate surfaces, to selectively etch or remove materials or coatings, oxidize or reduce materials present on the surface, and to improve roughness or smoothness of the uncoated and coated substrate surfaces by selectively removing or etching high points and/or low points. These surface treatment techniques are known to be effective in changing one or more optical characteristics such as light absorption, transmission, reflection and/or scattering of uncoated or coated substrates.

Although the use of an in-situ plasma activated reactive gas system is effective in treating materials, treatment with an in-situ activated reactive gas system is limited to small surface areas (e.g., substrates having a diameter ranging from 4 to 12 inches for microelectronic applications and dimensions up to 3 feet in width and up to 6 feet in length for flat panel display applications), surfaces that are not prone to damage caused by ion bombardment, and/or surfaces that require crude surface modification. Furthermore, it has been difficult to implement in-situ plasma activation of a reactive gas system for treating wide and/or long surface areas of materials precisely, uniformly and reproducibly. Similarly, treatment with a remote plasma activated reactive gas system has, thus far, been limited to small surface areas. It has been difficult to implement a remote activated reactive gas treatment system to modify or treat materials having wide and/or long surface areas precisely, uniformly, and reproducibly. The problems are believed to be related to distribution of activated reactive gas uniformly in the processing chamber and loss in activity of the activated reactive gas due to recombination of the activated species present within the activated reactive gas. Therefore, there is a need to develop a reactive gas treatment system that is suitable for treating, modifying or etching wide and/or long areas of a substrate, avoids damage to the substrate by ion bombardment, distributes activated reactive gas uniformly over the wide and/or long surface areas of substrates without significantly losing treatment effectiveness due to recombination of activated species present in the activated reactive gas.

### BRIEF SUMMARY OF THE INVENTION

An apparatus and process for treating at least a portion of the surface of a substrate is described herein. In one aspect there is provided an apparatus for treating at least a portion of a surface of a substrate having a width and/or a length of four feet or greater with an activated reactive gas comprising: a processing chamber comprising an inner volume, the substrate, and an exhaust manifold; an activated reactive gas supply source wherein a process gas comprising a reactive gas and optionally an additive gas is activated by an energy source to provide the activated reactive gas; and a distribution conduit, which is in fluid communication with the inner volume and the supply source, comprising: a plurality of openings that direct the activated reactive gas into the inner volume, wherein the activated reactive gas contacts the surface and provides a spent activated reactive gas and/or volatile products that are withdrawn from the inner volume through the exhaust manifold.

In another aspect, there is provided a process for treating at least a portion of a surface of substrate having a width and/or a length of four feet or greater, comprising: providing the substrate within an inner volume of a processing chamber comprising the inner volume, an exhaust manifold, and a distribution conduit comprising a plurality of openings wherein the distribution conduit is in fluid communication with the inner volume and an activated reactive gas supply source; supplying energy to a process gas comprising a reactive gas and optionally an additive gas to provide the activated reactive gas supply source; passing the activated reactive gas from the activated reactive gas supply source through the distribution conduit wherein the activated reactive gas flows through the openings and into the inner volume; contacting at least a portion of the surface with the activated reactive gas to treat the surface; and removing a spent activated reactive gas and/or volatile product from the inner volume through the exhaust manifold.

### BRIEF DESCRIPTION OF SEVERAL VIEWS OF THE DRAWINGS

FIG. 1 provides a top view of one embodiment of the apparatus described herein that is used to treat the wide and/or long surface of a substrate wherein the substrate is treated using a remotely activated process gas.

FIG. 2 provides a side view of the apparatus of FIG. 1 taken along cross- sectional line A-A′.

FIG. 3 provides a cross-sectional view of one embodiment of the distribution conduit of FIG. 1.

FIG. 4 provides a detailed view of the one embodiment of an opening within the distribution conduit shown in FIG. 3.

FIG. 5 provides a top view of one embodiment of the distribution conduit of FIG. 1 taken along cross-sectional line B-B′.

FIG. 6 provides a side view of another embodiment of the apparatus described herein wherein the substrate is treated using an in situ activated process gas.

### DETAILED DESCRIPTION OF THE INVENTION

An apparatus and process are described herein for treating wide (e.g., 4 feet wide or greater or ranging from 4 feet to 15 feet wide) and/or long (e.g., 4 feet long or greater or ranging from 5 to 25 feet long) surface areas of substrates precisely, uniformly and reproducibly. The term “surface treatment” as used herein describes a process wherein at least one characteristic of the surface is changed during and/or after the process is completed. Examples of surface treatments include, but are not limited to, surface smoothening, surface roughening, surface reduction, surface oxidation, surface nitriding, surface carburization, surface carbonitriding, surface fluorination and/or etching processes. Depending upon the material of the substrate (or the material of the coating disposed upon the substrate), the surface treatment apparatus and process described herein may result in the substrate exhibiting one or more of the following characteristics: improved adhesion and/or bonding to other materials; altered gas and liquid permeation properties; altered hydrophilic or hydrophobic properties; a surface substantially free of undesirable surface contaminants such as moisture, oil, etc.; and/or altered optical characteristics such as light absorption, transmission, reflection and scattering.

The apparatus and process described herein treats wide and/or long surfaces of a substrate by contacting at least a portion of the wide and/or long surface with an activated reactive gas. The term “activated reactive gas” describes at least a portion of a process gas comprising one or more reactive gases that is activated by exposure to one or more energy sources to provide active species, i.e., atoms, radicals, electrons, ions, etc. At least one of the characteristics of the treated surface is altered by contact with the activated reactive gas. The residual activated reactive gas and/or by-product of the reaction such as volatile products between the surface and the activated reactive gas may be readily removed by the vacuum pump of the processing chamber or other means. In certain embodiments, the product of the reaction between at least a portion of the substrate surface -which may be a solid, non-volatile material- and the activated reactive gas may be a species having a relatively higher volatility. In these embodiments, the term “volatile products”, as used herein, relates to reaction products and by-products of the reaction between the treated surface to be removed and the activated species of a reactive gas comprising one or more gases.

The activated reactive gas is distributed inside the processing chamber using a distribution system that enables sufficient exposure of the wide and/or long surface areas to the activated reactive gas and minimizes the loss in effectiveness of the activated species contained within the activated reactive gas due to recombination of activated species. In certain embodiments, the substrate having a wide and/or long surface area to be treated can be mounted on a conveyor system to enable continuous surface modification or treatment. In these embodiments, the substrate may be moved and the processing chamber is fixed in place. In alternative embodiments, at least a portion of the processing chamber may be movable with respect to the substrate to enable continuous surface modification or treatment. In the later embodiments, the substrate may be fixed in place.

The apparatus and process described herein is used to treat at least a portion of the wide and/or long area of a substrate. Exemplary substrates that may be treated include, but are not limited to, semiconductor materials such as gallium arsenide (“GaAs”), boronitride (“BN”), silicon, and compositions containing silicon such as crystalline silicon, polysilicon, amorphous silicon, epitaxial silicon, silicon dioxide (“SiOₓ or SiO₂”), silicon carbide (“SiC”), silicon oxycarbide (“SiOₓC_{y}”), silicon nitride (“SiNₓ”), silicon carbonitride (“SiCₓN_{y}”), a wide variety of glasses including float glass, soda lime glass, and borosilicate glass, organosilicate glasses (“OSG”), organofluorosilicate glasses (“OFSG”), fluorosilicate glasses (“FSG”), metals, semi-metals, polymers, plastics, ceramics and other appropriate substrates or mixtures thereof. Substrates may further comprise a variety of layers or coatings to which the film is applied thereto such as, for example, antireflective coatings, antiscratch coatings, hard coatings such as silicon oxide, silicon nitride, silicon carbonitrides, and titania, low-emission coatings deposited by chemical vapor deposition or physical vapor deposition, photoresists, organic polymers, porous organic and inorganic materials, metals such as copper and aluminum, thermal barrier layer, and/or diffusion barrier layers such as binary and/or transition metal ternary compounds.

At least a portion of a process gas comprising one or more reactive gases is activated by one or more energy sources to form an activated reactive gas. The amount of reactive gas present within the process gas may range from about 0.1% to about 100%, from about 0.5% to about 50%, or from about 1% to about 25% based upon the total volume of process gas. Exemplary reactive gases used for treating at least a portion of the substrate surface include, but are not limited to, halogen-containing gases (e.g., fluorine, chlorine, bromine, etc.), oxygen-containing gases, nitrogen-containing gases, and mixtures thereof. The process gas and/or reactive gas(es) contained therein can be delivered to the activation site by variety of means, such as, but not limited to, conventional cylinders, safe delivery systems, vacuum delivery systems, and/or solid or liquid-based generators that create the reactive source at the point of use.

In certain embodiments, the reactive gas may comprise a fluorine-containing gas. Examples of fluorine-containing gases suitable for the process described herein include: HF (hydrofluoric acid), F₂ (fluorine), NF₃ (nitrogen trifluoride), SF₆ (sulfur hexafluoride), SF₄ (sulfur tetrafluoride), sulfoxyfluorides such as SOF₂ (thionyl fluoride) and SO₂F₂ (sulfuryl floride), FNO (nitrosyl fluoride), XeF₂ (xenon fluoride), BrF₃ (bromine fluoride), C₃F₃N₃ (cyanuric fluoride); perfluorocarbons such as CF₄, C₂F₆, C₃F₈, C₄F₈ etc., hydrofluorocarbons such as CHF₃ and C₃F₇H etc., oxyfluorocarbons such as C₄F₈O (perfluorotetrahydrofuran), C₂F₂O₂ (oxalyl fluoride), COF₂, etc., oxygenated hydrofluorocarbons such as hydrofluoroethers (e.g. methyltrifluoromethyl ether —CH₃OCF₃), hypofluorites such as CF₃—OF (fluoroxytrifluoromethane (FTM)) and FO—CF₂—OF (bis-difluoroxy-difluoromethane (BDM)), etc., fluoroperoxides such as CF₃—O—O—CF₃ (bis-trifluoro-methyl-peroxide (BTMP)), F—O—O—F etc., fluorotrioxides such as CF₃—O—O—O—CF₃ etc., fluoroamines such a CF₅N (perfluoromethylamine), fluoronitriles such as C₂F₃N (perfluoroacetonitrile), C₃F₆N (perfluoroproprionitrile), and CF₃NO (trifluoronitrosylmethane), and COF₂ (carbonyl fluoride).

In certain embodiments, the reactive gas may comprise a chlorine-containing gas. Examples of chlorine-containing gases suitable for the process described herein include BCl₃, COCl₂, HCl, Cl₂, ClF₃, and NFₓCl₃₋ₓ, where x is an integer from 0 to 2, chlorocarbons, and chlorohydrocarbons (such as CₓH_{y}Cl_{z} where x is a number ranging from 1 to 6, y is a number ranging from 0 to 13, and z is a number ranging from 1 to 14).

In certain embodiments, the reactive gas can further contain an oxygen- containing gas. Exemplary oxygen-containing gases include O₂, O₃, CO, CO₂, NO₂, H₂O, and N₂O.

In embodiments wherein the process gas is not entirely comprised of reactive gas(es), the process gas also comprises one or more additive gases. Examples of additive gases include hydrogen, nitrogen, helium, neon, argon, krypton, and xenon. It is believed that, in certain embodiments, the additive gas can modify the plasma characteristics to better suit some specific applications. In these and other embodiments, the additive gas may also aid in transporting the reactive gas and/or activated reactive gas to the substrate or process chamber. The amount of additive gas present within the process gas may range from 0% to 99.9%, or from about 25% to about 99.5%, or from 50% to about 99.5%, or from about 75% to about 99.9%, by volume based upon the total volume of process gas.

The reactive gas within the process gas may be activated by one or more energy sources such as, but not limited to in situ plasma, remote plasma, remote thermal/catalytic activation, in-situ thermal heating, electron attachment, and photo activation. These processes may be used alone or in combination.

In thermal heating activation, the processing chamber and apparatus contained therein may be heated either by resistive heaters or by intense or infrared lamps. Reactive gases are thermally decomposed remotely into active species, i.e., reactive radicals and atoms that subsequently react with at least a portion of the substrate surface. Elevated temperature may also provide the energy source to overcome reaction activation energy barrier and enhance the reaction rates. For thermal activation, the substrate can be heated to at least 50° C., or at least 300° C., or at least 500° C. In embodiments wherein at least one of the fluorine-containing gases is NF₃, the substance can be heated up to at least 300° C., or at least 400° C., or at least 600° C. In these embodiments, the temperature may range from about 450° C. to about 700° C. Different reactive gases may use different temperature ranges. For example, if the reactive gas contains ClF₃ or F₂ as the fluorine-containing gas, the temperature may range from about 100° C. to about 700° C. In any of these embodiments, the pressure may range from 10 mTorr to 760 Torr, or from 1 Torr to 760 Torr.

In embodiments wherein an in situ plasma source is used to activate the reactive gas, fluorine-containing gas molecules such as NF₃ may be broken down by the discharge to form reactive fluorine-containing ions and radicals. The fluorine-containing ions and radicals can react with the surface of the substrate to form volatile species that can be removed from the process chamber by vacuum pumps or similar means. For in situ plasma activation, the in situ plasma can be generated with a 13.56 MHz RF power supply, with RF power density of at least 0.2 W/cm², or at least 1 W/cm², or at least 3 W/cm². Alternatively, the in situ plasma can be operated at RF frequencies lower or higher than 13.56 MHz. The in-situ plasma can also be generated by DC discharge. The operating pressure may range from 2.5 mTorr to 100 Torr, or from 5 mTorr to 50 Torr, or from 10 mTorr to 20 Torr. In one particular embodiment, the process is conducted at a pressure of 5 torr or less. In these embodiments, an in situ energy source, such as in situ RF plasma thermal activation can be can be combined with a thermal and/or remote energy source.

In certain preferred embodiments, a remote energy source, such as, but not limited to, a remote plasma source such as RF, DC discharge, microwave, or ICP activation, a remote thermal activation source, and/or a remote catalytically activated source (i.e., a remote source which combines thermal and catalytic activation), can be used to activate the reactive gas. In remote plasma activation, the process gas having reactive gas contained therein is activated to form an activated reactive gas outside of the processing chamber which is introduced into the processing chamber to treat at least a portion of the substrate. In remote thermal activation, the process gas first flows through a heated area outside of the process chamber. The gas dissociates by contact with the high temperatures within in a location outside of the process chamber. Alternative approaches include the use of a remote catalytic converter to dissociate the process gas, or a combination of thermal heating and catalytic cracking to facilitate activation of the reactive gas within the process gas. In these embodiments, reactions between remote plasma generated reactive species and the substrate surface can be activated/enhanced by heating the substrate to temperatures of at least 100° C., or at least 300° C., or at least 400° C., or at least 600° C.

The remotely activated reactive gas is distributed inside a vacuum chamber using an apparatus that is designed to provide uniform and complete coverage of the wide and/or long surface areas of material with activated reactive gas and to minimize the loss in effectiveness of the activated species present in the activated reactive gas due to recombination of the activated species.

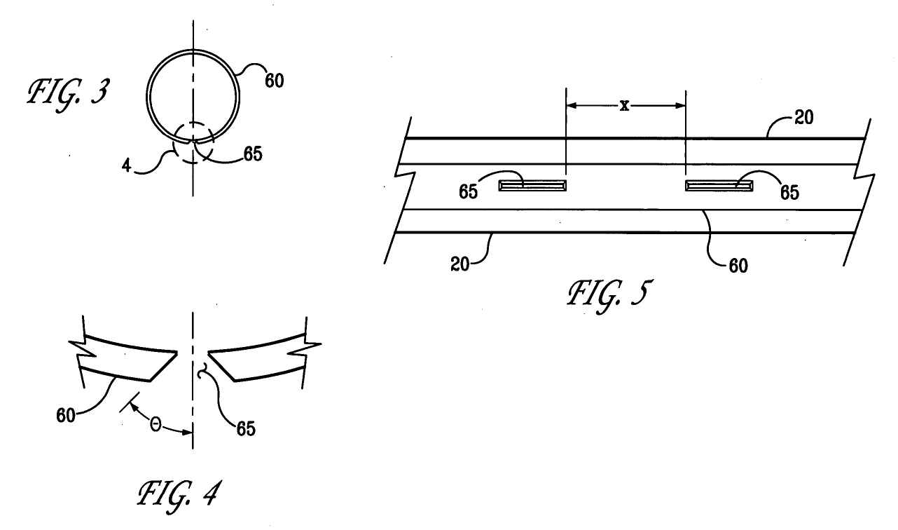

FIGS. 1 through 5 provide an example of one embodiment of the apparatus for introducing a remotely activated reactive gas described herein. Apparatus 10 is comprised of a processing chamber 20 where at least a portion of the surface of the substrate 70 (shown in dotted line in FIG. 1) is treated, an activated reactive gas supply source 50, a distribution conduit 60 (shown in dashed line in FIG. 1), an exhaust manifold 30, and outlet 40 to a vacuum pump (not shown). Distribution conduit 60 has a substantially continuous inner volume that is in fluid communication with supply source 50 of the activated species of the process gas, such as for example, a remote plasma activation chamber, and the inner volume 25 of processing chamber 20. Distribution conduit 60 may have a circular, elliptical, ovular, square, or rectangular cross section. In certain embodiments, the distribution conduit has a rounded cross-section such as a circular, elliptical, ovular, etc., to facilitate flow of the activated species through the conduit and minimize areas of stagnation. In the embodiment depicted in FIGS. 1 through 5, distribution conduit is a cylindrical pipe. In these embodiments, the inner diameter of the pipe may be at least one inch or greater.

Distribution conduit 60 has a plurality of openings 65 (see FIGS. 1 and 3 through 5) which allows the activated reactive gas to flow from supply source 50 to inner volume 25 of processing chamber 20. In certain embodiments, the maximum total cross- sectional area of the openings, or the sum of the cross-sectional areas of openings 65 within distribution conduit 60, may be selected by providing the ratio of kinetic energy of the inlet stream of activated reactive gas into distribution conduit 60 to pressure drop across opening 65 to be equal to or less than one-tenth. For example, the maximum total cross sectional area of the openings for a distributor conduit with slightly more than 1″ inside diameter is approximately 1 square inches (in²) or less. Openings 65 may have a variety of geometries including but not limited to, circular, square, rectangular, oval, etc. Openings 65 in the distribution conduit 60 may exhibit any geometry as long as the criteria related to the maximum total cross-sectional area is maintained. In embodiments wherein the geometry of opening 65 is rectangular in shape, it is preferred to orient the longest dimension of opening 65 parallel to the gas flow along the distribution conduit 60. In certain embodiments, such as that shown in FIG. 4, the sidewalls of opening 65 may be angled or chamfered at an angle θ of at least 20° or greater, or at least 30° or greater or at least 45° or greater, to minimize the amount of contact of activated reactive gas with the side walls. To improve the flow of the activated reactive gas through distribution conduit 60, at least one end 63 of the distribution conduit 60, or the end opposite the activated reactive gas inlet 61, is closed.

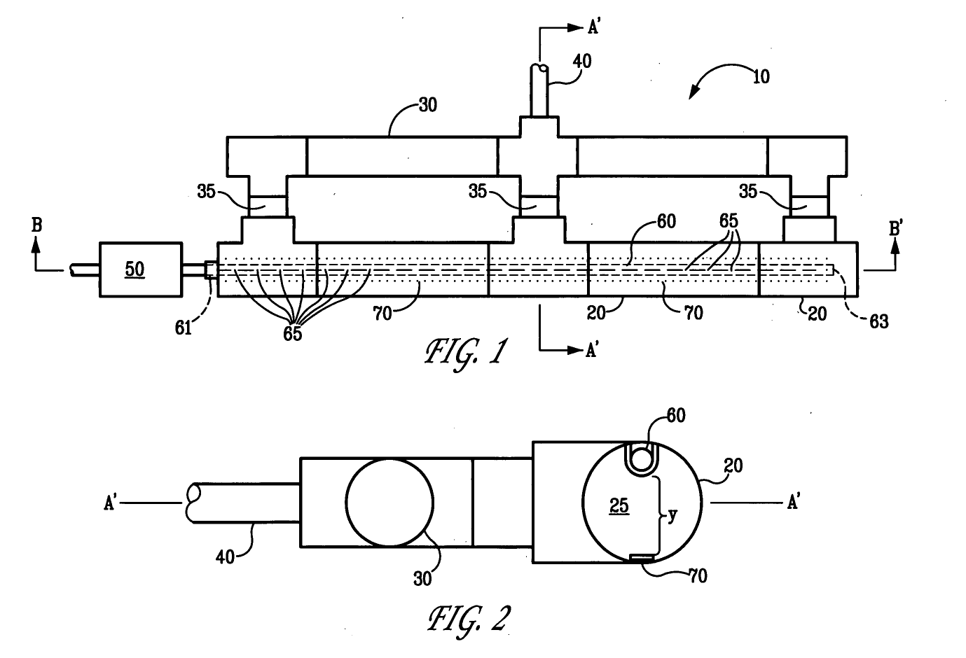

In certain embodiments, uniform distribution of activated reactive gas along the length of distribution conduit 60 can be achieved by carefully selecting the distance “x” (see FIG. 5) between two of the plurality of openings 65 in distribution conduit 60 and/or the distance “y” (see FIG. 2) between opening 65 and the surface of the substrate 70 to be treated. The measurements for “x” and “y” may vary depending upon the geometry and features of apparatus 10. In certain embodiments, distance “y” may range from about 2 to about 8 inches or from about 2 to about 6 inches. In these embodiments, distance ‘y’ may be also used to calculate the appropriate chamfer angle and geometry of opening 65. For example, the maximum cross sectional area of each opening 65 can be calculated by dividing the maximum total cross sectional opening flow area by the total number of openings desired along the length of the distribution conduit 60. The information about the desired number of openings and shape and size of the openings is then used to determine the distance “x” assuming that the flow of activated reactive gas diverged by an angle of 10° in each direction once it passed by the edge of the opening 65. The shape and size of the openings and the pitch that provide overlap of the gas passing from each opening when it reaches the substrate surface then determines the pitch of the opening.

The spent activated reactive gas, and/or volatile products if present, may be removed from inner volume 25 of the processing chamber 20 via one or more conduits 35 to a common exhaust manifold 30. The spent reactive gas is then exhausted out of the common exhaust manifold 30 via outlet 40 to a vacuum pump (not shown). In certain embodiments, the spent activated reactive gas can be treated to remove harmful components prior to venting to outside environment and/or recycling back into supply source 50.

The time of flight of activated reactive gas, from supply source 50 to inner volume 25 to surface of substrate 70, may vary depending upon one or more of the following operating parameters such as, for example, the total operating pressure of apparatus 10 (which includes the flow rate of activated reactive gas and any additional additive gases), distance of flow from supply source 50 to substrate 70, mass flow rate of reactive gas, mass flow rate of other additive gases combined with the activated reactive gas, etc. In certain embodiments, any one or more of the foregoing operating parameters are varied to provide a time of flight of activated species of about 1.0 second or less or about 0.5 seconds or less. In these embodiments, the operating pressure in the processing chamber can vary from about 1 millitorr to about 100 torr, or from about 5 millitorr to about 50 torr, or from about 5 millitorr to about 10 torr.

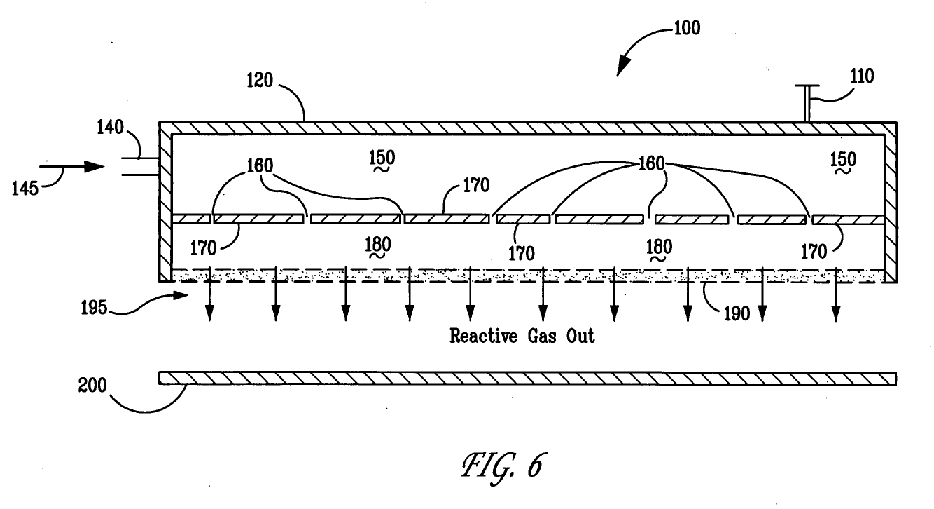

In certain embodiments, the reactive gas can be distributed inside a vacuum chamber for in-situ activation using an apparatus that is designed to provide uniform and complete coverage of the wide and/or long surface areas of material with activated reactive gas. FIG. 6 provides an example of one such embodiment of the apparatus described herein for introducing reactive gas for in-situ activation. Apparatus 100 is comprised of a distribution conduit 120 mounted inside a processing chamber (not shown) where at least a portion of the surface of substrate 200 is treated. The reactive gas distribution chamber is comprised of a closed-ended, hollow distribution conduit 120 and a process gas inlet 140 for providing uniform distribution of the process gas into the processing chamber. Process gas flows into distribution conduit 120 through inlet 140 as shown by arrow 145. In certain embodiments, an exhaust manifold (not shown) is attached via exhaust outlet to the processing chamber to facilitate evacuation of used or spent activated reactive gas with a vacuum pump (not shown). In certain embodiments, distribution chamber 120 further includes a perforated or porous, metallic or ceramic layer 190 that has a perforation or pore size greater than the mean free path of the reactive gas used for treating the surface of the substrate. The process gas is fed to the upper portion 150 of the distribution conduit 120 through an inlet pipe 140 connected to the process gas supply source (not shown). The hollow metallic distribution chamber may include a distribution baffle 170 containing multiple, uniformly spaced apertures 160 designed to distribute the reactive gas uniformly throughout the length of the bottom portion 180 of distribution conduit 120. In one particular embodiment, baffle 170 separating the upper and lower portions 150 and 180 of distribution conduit 120 may consists of, for example, a stainless steel plate having holes ranging in size from 1 to 2 millimeter (mm) that are spaced every 10 to 20 centimeter (cm) along the main axis of the plate. The perforated or porous layer 190 can have size of perforation or pores varying from 0.1 microns to about 50 microns. In certain embodiments, baffle 170 may allow for the gas pressure against the bottom porous layer 190 to be uniform and consistent through feed fluctuations. Porous layer 190 is made of metallic or ceramic material for in-situ thermal and/or catalytic activation of reactive gas. In embodiments wherein the reactive gas is activated by in-situ plasma activation, porous layer 190 comprises a metallic material. In these embodiments, RF power is applied through a power line 110 for in-situ activation of reactive gas with plasma. The activated reactive gas flows out of distribution conduit 120 through porous layer 120 as shown by arrows 195 and contacts at least a portion of the surface of substrate 200. Like distribution chamber in FIG. 1, distribution chamber 120 may have a circular, elliptical, ovular, square, or rectangular cross section.

In certain embodiments, a large portion of the surface area of the substrate may be treated at one time by covering the entire width of the material by the distribution system and moving the substrate on a conveyor belt. Alternatively, the distribution conduit can be moved with respect to the substrate and the substrate is fixed in place. In these embodiments, the distribution conduit may substantially cover the width of the substrate but only a portion of the length of the substrate. This may allow a single distribution conduit to treat substantially the entire width and a segment of the length of the substrate. The entire length of the substrate can then be treated by controlling speed of the conveyor belt and/or the distribution conduit(s). In alternative embodiments, a plurality of distribution conduits may be used. In these embodiments, the distribution conduits may be placed in parallel or in other configurations to cover part of the length of the material. For substrates having a width of eight feet or greater, two or more distribution conduits, each conduit being from 6 to 8 feet in length can be arranged consecutively from either side of the substrate to substrate surface that is 16 to 18 feet wide. In still further embodiments, the main feed into the distribution conduits from the supply source can be split into parallel pipes to cover at least a portion of the length of the substrate. It is believed that using a plurality of distribution conduits may prevent the active species within the activated reactive gas from recombining if the length of the distribution conduit becomes too long or the residence time of activated reactive gas in the distribution conduit is too greater. In this and other embodiments, multiple activation supply sources may be employed to feed one or more multiple distribution conduits.

In one embodiment of the method described herein, a large substrate having a length of 4 feet or greater and/or a width of 4 feet or greater is placed onto a conveyor belt that is passed into a processing chamber. The processing chamber has a distribution conduit that is mounted perpendicular to the mouth of the processing chamber and has multiple openings through which an activated reactive gas passes through. The activated reactive gas contacts at least a portion of the substrate surface and forms a spent activated reactive gas and/or volatile by-product. The spent activated reactive gas and/or volatile by-products pass out of the processing chamber through exhaust manifold by a vacuum pump. In certain embodiments, it may be desirable to preheat the surface to be treated to improve efficiency of surface treatment by activated reactive gas. Therefore, the surface to be treated can be pre-heated to a temperature varying from ambient temperature to about 50° C., or from ambient temperature to about 250° C., or from ambient temperature to about 400° C.

### EXAMPLES

A system, that uses a remote plasma energy source to activate the reactive gas within the process gas and is similar to that depicted in FIGS. 1 through 5, was used to treat surfaces of materials in a vacuum processing chamber that was 10 inches in diameter and slightly more than eight feet long. The system was comprised of an 8-foot (ft) long, circular distribution conduit or pipe having a 1.5 inch (in) inner diameter. The distribution pipe further contained 18 rectangular shaped openings for introducing an activated reactive gas. These openings were equally spaced along the length of the pipe and were directed towards the inner volume of the processing chamber. Each rectangular-shaped opening was 1.5 in length and 0.031 in width. The cross-sectional flow area of all 18 openings was 0.84 in². Both dimensions (e.g., length and width) of the openings were chamfered to about 20° to minimize contact of the activated reactive gas with the openings. The distribution pipe was mounted along the top of the processing chamber with the openings facing down into the inner volume of the processing chamber. The substrate to be treated was placed at a distance from the openings that measured from 2 to 6 inches. The distribution pipe was sealed at one end and open at the opposite end. An activated reactive gas was introduced into the pipe through the open end that was in fluid communication with an activation source for the reactive gas. The reactive gas was activated in a location outside of the vacuum processing chamber using a 13.56 MHz RF ASTRON™ plasma source manufactured by MKS Instruments of Wilmington, Mass. The activated reactive gas passed through and exited the pipe via the openings and contacted the surface of the substrate to be treated. The spent activated reactive gas, along with volatile products formed during the treatment, was evacuated from the vacuum processing chamber using a vacuum pump.

In some of the following examples, the surface roughness numbers were reported as an average; in other examples, the surface roughness numbers were reported as a range.

### Example 1

The vacuum processing chamber described above was used to treat the surface of two 4″ diameter silicon wafers that were thermally treated in the presence of an oxygen-containing gas to provide an approximately 470 nanometer (nm) thick silicon oxide layer with an average root mean square (rms) surface roughness of approximately 0.43 nm. The wafers were placed within the vacuum processing chamber in a location that was 8 inches and 7.5 feet from the entrance of the activated gas into the processing chamber, respectively, to approximate the extreme ends of the processing chamber. The wafers were placed on the two extreme ends to simulate treatment of an approximately 8 foot wide substrate surface. The processing chamber was operated at a pressure of about 1.4 torr. The distribution pipe was supplied with a 1000 standard cubic centimeter per minute (sccm) flow of NF₃ gas that was activated using the external RF plasma source described above. The distance of wafers from the opening was approximately 6 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were removed for analysis. The analytical results showed that from about 60 to about 100 nm of silicon oxide layer was removed from these wafers with minor changes in the surface roughness—the surface roughness improved from about 0.43 nm to a value varying between 0.31 to 0.39 nm.

### Example 2

The surface treatment of two 4″ diameter silicon wafers with approximately 470 nanometer (nm) thick silicon oxide layer described in Example 1 was repeated in the same vacuum chamber with similar placement of wafers. The vacuum chamber was operated at a pressure of about 0.94 torr instead of using 1.4 torr pressure. The distribution pipe was supplied with a 3000 standard cubic centimeter per minute (sccm) flow of NF₃ gas that was activated using the external RF plasma source described above. The distance of wafers from the opening was approximately 6 inches. These wafers were exposed to activated NF₃ gas for a total time of 2 minutes. Thereafter, the flow of activated NF₃ gas was terminated, the distribution pipe and vacuum chamber were purged with argon gas, and the treated wafers were removed for analysis. The analytical results showed that from about 60 to about 90 nm of silicon oxide layer was removed from these wafers. The surface roughness of silicon oxide layer was noted to improve considerably from about 0.43 nm to about 0.24 nm.

### Example 3

The surface treatment of two 4″ diameter silicon wafers with approximately 470 nanometer (nm) thick silicon oxide layer described in Example 1 was repeated in the same vacuum chamber with similar placement of wafers. The vacuum chamber was operated at a pressure of about 1.4 torr. The distribution pipe was supplied with a 3000 standard cubic centimeter per minute (sccm) flow of NF₃ gas that was activated using the external RF plasma source described above. The distance of wafers from the opening was approximately 2 inches instead of using 6 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were removed for analysis. The analytical results showed that from about 120 to about 250 nm of silicon oxide layer was removed from these wafers. The surface roughness of silicon oxide layer was noted to become worse from about 0.43 nm to a value varying between 0.43 and 0.76 nm.

### Example 4

The surface treatment of two 4″ diameter silicon wafers with approximately 470 nanometer (nm) thick silicon oxide layer described in Example 1 was repeated in the same vacuum chamber with similar placement of wafers. The vacuum chamber was operated at a pressure of about 1.4 torr. The distribution pipe was supplied with a 1000 standard cubic centimeter per minute (sccm) flow of a 50-50 mixture of NF₃ and argon gases. The mixture was was activated using the external RF plasma source described above. The distance of wafers from the opening was approximately 2 inches. These wafers were exposed to activated NF₃ gas for a total time of 2 minutes. Thereafter, the flow of activated NF₃ gas was terminated, the distribution pipe and vacuum chamber were purged with argon gas, and the treated wafers were removed for analysis. The analytical results showed that from about 92 nm of silicon oxide layer was removed from these wafers. The surface roughness of silicon oxide layer was noted to improve from about 0.43 nm to about 0.34 nm.

### Example 5

The surface treatment of two 4″ diameter silicon wafers with approximately 470 nanometer (nm) thick silicon oxide layer described in Example 4 was repeated in the same vacuum chamber with similar placement of wafers. The vacuum chamber was operated at a pressure of about 0.94 torr. The distribution pipe was supplied with a 3000 standard cubic centimeter per minute (sccm) flow of a 50-50 mixture of NF₃ and argon gases. The mixture was was activated using the external RF plasma source described above. The distance of wafers from the opening was approximately 2 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were removed for analysis. The analytical results showed that from about 120 to 160 nm of silicon oxide layer was removed from these wafers. The surface roughness of silicon oxide layer was noted not to change much after the treatment.

### Example 6

The surface treatment of two 4″ diameter silicon wafers with approximately 470 nanometer (nm) thick silicon oxide layer described in Example 4 was repeated in the same vacuum chamber with similar placement of wafers. The vacuum chamber was operated at a pressure of about 0.94 torr. The distribution pipe was supplied with a 1000 standard cubic centimeter per minute (sccm) flow of a 50-50 mixture of NF₃ and argon gases. The mixture was activated using the external RF plasma source described above. The distance of wafers from the opening was approximately 6 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were removed for analysis. The analytical results showed that from about 20 nm of silicon oxide layer was removed from these wafers. The surface roughness of silicon oxide layer was noted to degrade from about 0.43 nm to about 0.7 nm.

### Example 7

The procedure of Example 1 was repeated except on two 4″ diameter silicon wafers that were deposited with an approximately 300 nm thick silicon nitride coating that was deposited via plasma enhanced chemical vapor deposition technique. The average root mean square (rms) surface roughness of the silicon nitride coating was approximately 0.73 nm. The processing chamber was operated at a pressure of about 0.94 torr. The distribution pipe was supplied with 1000 sccm flow of NF₃ gas that was activated using an external RF plasma source. The distance of wafers from the opening was approximately 2 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were taken out for analysis. The analytical results showed that from about 90 to 170 nm of silicon nitride coating was removed from these wafers. The surface roughness of the silicon nitride coating increased from approximately 0.73 nm to from about 7.4 to 9.5 nm.

### Example 8

The procedure of Example 7 was repeated except on two 4″ diameter silicon wafers that were deposited with an approximately 300 nm thick silicon nitride coating that was deposited via plasma enhanced chemical vapor deposition technique. The processing chamber was operated at a pressure of about 1.4 torr. The distribution pipe was supplied with 1000 sccm flow of NF₃ gas that was activated using an external RF plasma source. The distance of wafers from the opening was approximately 6 inches. These wafers were exposed to activated NF₃ gas for a total time of 2 minutes. Thereafter, the flow of activated NF₃ gas was terminated, the distribution pipe and vacuum chamber were purged with argon gas, and the treated wafers were taken out for analysis. The analytical results showed that about 100 nm of silicon nitride coating was removed from these wafers. The surface roughness of the silicon nitride coating increased slightly from approximately 0.73 nm to about 2.0 nm.

### Example 9

The procedure of Example 7 was repeated except on two 4″ diameter silicon wafers that were deposited with an approximately 300 nm thick silicon nitride coating that was deposited via plasma enhanced chemical vapor deposition technique. The processing chamber was operated at a pressure of about 0.94 torr. The distribution pipe was supplied with 3000 sccm flow of NF₃ gas that was activated using an external RF plasma source. The distance of wafers from the opening was approximately 6 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were taken out for analysis. The analytical results showed that from about 100 to 120 nm of silicon nitride coating was removed from these wafers. The surface roughness of the silicon nitride coating increased slightly from approximately 0.73 nm to about 1.3 nm.

### Example 10

The procedure of Example 7 was repeated except on two 4″ diameter silicon wafers that were deposited with an approximately 300 nm thick silicon nitride coating that was deposited via plasma enhanced chemical vapor deposition technique. The processing chamber was operated at a pressure of about 0.94 torr. The distribution pipe was supplied with 1000 sccm flow of a 50-50 mixture of NF₃ and argon gases. The mixture was activated using an external RF plasma source. The distance of wafers from the opening was approximately 6 inches. These wafers were exposed to activated NF₃ gas for a total time of 2 minutes. Thereafter, the flow of activated NF₃ gas was terminated, the distribution pipe and vacuum chamber were purged with argon gas, and the treated wafers were taken out for analysis. The analytical results showed that about 60 nm of silicon nitride coating was removed from these wafers. The surface roughness of the silicon nitride coating increased from approximately 0.73 nm to about 7.0 nm.

### Example 11

The procedure of Example 7 was repeated except on two 4″ diameter silicon wafers that were deposited with an approximately 300 nm thick silicon nitride coating that was deposited via plasma enhanced chemical vapor deposition technique. The processing chamber was operated at a pressure of about 1.4 torr. The distribution pipe was supplied with 1000 sccm flow of a 50-50 mixture of NF₃ and argon gases. The mixture was activated using an external RF plasma source. The distance of wafers from the opening was approximately 2 inches. These wafers were exposed to activated NF₃ gas for a total time of 3 minutes. Thereafter, the flow of activated NF₃ gas was terminated, the distribution pipe and vacuum chamber were purged with argon gas, and the treated wafers were taken out for analysis. The analytical results showed that from about 60 to 90 nm of silicon nitride coating was removed from these wafers. The surface roughness of the silicon nitride coating increased slightly from approximately 0.73 nm to about 1.3 nm.

### Example 12

The procedure of Example 7 was repeated except on two 4″ diameter silicon wafers that were deposited with an approximately 300 nm thick silicon nitride coating that was deposited via plasma enhanced chemical vapor deposition technique. The processing chamber was operated at a pressure of about 0.94 torr. The distribution pipe was supplied with 3000 sccm flow of a 50-50 mixture of NF₃ and argon gases. The mixture was activated using an external RF plasma source. The distance of wafers from the opening was approximately 2 inches. These wafers were exposed to activated NF₃ gas for a total time of 2 minutes. Thereafter, the flow of activated NF₃ gas was terminated, the distribution pipe and vacuum chamber were purged with argon gas, and the treated wafers were taken out for analysis. The analytical results showed that from about 40 to 70 nm of silicon nitride coating was removed from these wafers. The surface roughness of the silicon nitride coating increased slightly from approximately 0.73 nm to about 1.1 nm.

1. An apparatus for treating at least a portion of a surface of a substrate having a length and/or a width of four feet or greater with an activated reactive gas, the apparatus comprising:
a processing chamber comprising an inner volume, the substrate, and an exhaust manifold;
an activated reactive gas supply source wherein a process gas comprising a reactive gas and optionally an additive gas is activated by an energy source to provide the activated reactive gas; and
a distribution conduit, which is in fluid communication with the inner volume and the supply source, comprising: a plurality of openings that direct the activated reactive gas into the inner volume
wherein the activated reactive gas contacts the surface and provides a spent activated reactive gas and/or volatile products that are withdrawn from the inner volume through the exhaust manifold.

2. The apparatus of claim 1 wherein the energy source is selected from an in situ plasma energy source, a remote plasma energy source, a remote thermal energy source, a catalytic energy source, an in-situ thermal energy source, electron attachment, a photon-based energy source, and mixtures thereof.

3. The apparatus of claim 2 wherein the energy source comprises the remote plasma energy source.

4. The apparatus of claim 2 wherein the energy source comprises the in situ plasma energy source.

5. The apparatus of claim 1 wherein the reactive gas comprises an oxygen- containing gas selected from oxygen, ozone, nitric oxide, nitrous oxide, nitrogen dioxide, carbon monoxide, carbon dioxide, water, and mixtures thereof.

6. The apparatus of claim 1 wherein the reactive gas comprises a fluorine-containing gas; a perfluorocarbon; a hydrofluorocarbon; an oxyfluorocarbon; an oxygenated hydrofluorocarbon; a hydrofluoroether; a hypofluorite; a fluoroperoxide; a fluorotrioxide; a fluoroamine; a fluoronitrile; a sulfoxyfluoride; and mixtures thereof.

7. The apparatus of claim 6 wherein the fluorine-containing gas is selected from F₂; HF, NF₃; SF₆; SF₄; COF₂, NOF, C₃F₃N₃, and mixtures thereof.

8. The apparatus of claim 1 wherein the reactive gas comprises a chlorine-containing gas selected from BCl₃, COCl₂, HCl, Cl₂, ClF₃, NFₓCl₃₋ₓ, where x is an integer ranging from 0 to 2, chlorocarbons, chlorohydrocarbons, and mixtures thereof.

9. The apparatus of claim 1 wherein the process gas comprises the additive gas.

10. The apparatus of claim 9 wherein the additive gas is one selected from H₂, N₂, He, Ne, Kr, Xe, Ar, and mixtures thereof.

11. A process for treating at least a portion of a surface of substrate having a width and/or a length of four feet or greater, comprising:
providing the substrate within an inner volume of a processing chamber comprising the inner volume, an exhaust manifold, and a distribution conduit comprising a plurality of openings wherein the distribution conduit is in fluid communication with the inner volume and an activated reactive gas supply source;
supplying energy to a process gas comprising a reactive gas an optionally an additive gas to provide the activated reactive gas supply source;
passing the activated reactive gas from the activated reactive gas supply source through the distribution conduit wherein the activated reactive gas flows through the openings and into the inner volume;
contacting at least a portion of the surface with the activated reactive gas to treat the surface; and
removing a spent activated reactive gas and/or volatile product from the inner volume through the exhaust manifold.

12. The process of claim 11 wherein the energy is selected from an in situ plasma energy source, a remote plasma energy source, a remote thermal energy source, a catalytic energy source, an in-situ thermal energy source, electron attachment, a photon-based energy source, and mixtures thereof.

13. The process of claim 12 wherein the energy comprises the remote plasma energy source.

14. The process of claim 12 wherein the energy comprises the in situ plasma energy source.

15. The process of claim 11 wherein the reactive gas comprises an oxygen-containing gas selected from oxygen, ozone, nitric oxide, nitrous oxide, nitrogen dioxide, carbon monoxide, carbon dioxide, water, and mixtures thereof.

16. The process of claim 11 wherein the reactive gas comprises a fluorine-containing gas; a perfluorocarbon; a hydrofluorocarbon; an oxyfluorocarbon; an oxygenated hydrofluorocarbon; a hydrofluoroether; a hypofluorite; a fluoroperoxide; a fluorotrioxide; a fluoroamine; a fluoronitrile; a sulfoxyfluoride; and mixtures thereof.

17. The apparatus of claim 16 wherein the fluorine-containing gas is selected from F₂; HF, NF₃; SF₆; SF₄; COF₂, NOF, C₃F₃N₃, and mixtures thereof.

18. The process of claim 11 wherein the reactive gas comprises a chlorine-containing gas selected from BCl₃, COCl₂, HCl, Cl₂, ClF₃, NFₓCl₃₋ₓ, where x is an integer ranging from 0 to 2, chlorocarbons, chlorohydrocarbons, and mixtures thereof.

19. The process of claim 11 wherein the process gas comprises the additive gas.

20. The process of claim 19 wherein the additive gas is one selected from H₂, N₂, He, Ne, Kr, Xe, Ar, and mixtures thereof.
